(19) United States
(12) Patent Application Publication
(10) Pub. No.: US 2014/0091676 A1
(43) Pub. Date: Apr. 3, 2014

(54) CRYSTAL UNIT

(71) Applicant: NIHON DEMPA KOGYO CO., LTD., TOKYO (JP)

(72) Inventor: TOYOAKI KUSUNOKI, SAITAMA (JP)

(73) Assignee: NIHON DEMPA KOGYO CO., LTD., TOKYO (JP)

(21) Appl. No.: 14/034,570

(22) Filed: Sep. 24, 2013

(30) Foreign Application Priority Data
Sep. 28, 2012 (JP) 2012-217364

(51) Int. Cl. H03H 9/02

(52) U.S. Cl. CPC H03H 9/02015
USPC 310/360

(57) ABSTRACT

A crystal unit according to this disclosure includes an IT-cut round crystal element supported at two points on an outer periphery portion of the IT-cut round crystal element. A rotation angle in plane between a straight line connecting the two points and Z″ axis of a double-rotation is within a specific range. The specific range includes an angle where an amount of frequency variation is zero.

### CROSS REFERENCE TO RELATED APPLICATIONS

This application claims the priority benefit of Japan application serial no. 2012-217364, filed on Sep. 28, 2012. The entirety of the above-mentioned patent application is hereby incorporated by reference herein and made a part of this specification.

### TECHNICAL FIELD

The disclosure relates to a crystal unit that employs an IT-cut crystal element. Especially, the disclosure relates to a crystal unit with an improved aging characteristics and a reduced variation in environmental resistance characteristics.

### DESCRIPTION OF THE RELATED ART

A crystal unit with an IT-cut crystal element is available for an oven controlled crystal oscillator (OCXO) and similar. The crystal unit with the IT-cut crystal element is made of a double-rotation crystal element with electrodes formed on the double-rotation crystal element. The double-rotation crystal element is cut out from a crystal of quartz along a plane that is obtained by rotating a plane perpendicular to Y axis of crystal counter clockwise around X axis by approximately 34 degrees and then further rotating this plane around Z axis by approximately 19 degree from this rotated position.

### Rotation Angle in Plane

Z″ axis is defined as Z axis that is obtained by a double-rotation from Z axis and X axis of crystallographic axes counter clockwise, respectively. A crystal unit with a round crystal element is usually supported at two points on an outer periphery. A straight line (which is a diameter) that connects these two points forms an angle with Z″ axis. This angle is defined as a rotation angle in plane. The two points as the supporting points are disposed where the electrodes are formed. And, the double-rotation cut crystal unit has the rotation angle in plane Ψ from Z″ axis whose magnitude affects its vibration characteristic.

### Aging Characteristics of a Conventional IT-cut Crystal Unit (See FIG. 8)

An aging characteristic of a conventional IT-cut crystal unit will be described by referring to FIG. 8. FIG. 8 is a graph illustrating an example of aging characteristic of a conventional IT-cut crystal unit. As shown in FIG. 8, the horizontal axis indicates the number of days after the power turns on, and the vertical axis indicates a proportion (Δf/f) of a shift of the frequency. The conventional IT-cut crystal unit is observed to have a large frequency shift within approximately 10 days after the power turns on. This is thought to be caused by a gradual release of stress, which is applied when manufacturing the crystal unit, after the start of vibration. FIG. 8 indicates a case where a rotation angle in plane Ψ from Z″ axis is 0 degrees.

### Deviation in Rotation of a Crystal Element

In a conventional crystal unit, when supporting and securing a crystal element, the crystal element rotates to be displaced in angle. This causes a variation in resistance (environmental resistance characteristics) to environment of such as heat cycle and impact.

### Examples of an Environment Test and a Heat Cycle Test (See FIG. 9 and FIG. 10)

Here, a relationship between a rotation angle in plane and an amount of frequency variation of an SC-cut crystal unit, which is a double-rotation crystal unit, will be described by referring to FIG. 9 and FIG. 10. FIG. 9 is a graph illustrating a result of the heat cycle test. FIG. 10 is a graph illustrating a result of the drop test. In the heat cycle test, an amount of frequency variation was measured in the case where the SC-cut crystal unit was held for 30 minute at respective temperatures between −55° C. to +125° C. while varying the rotation angle in plane in a range of 0 degrees to 90 degrees for 100 cycles. FIG. 9 indicates the result including maximum, minimum, and average of the amount of frequency variation of the tested six samples. As shown in FIG. 9, the amount of frequency variation varies depending on a rotation angle in plane Ψ, and the amount of frequency variation has the maximum value in +direction at a rotation angle in plane Ψ of 45 degree.

### Drop Test (See FIG. 10)

In the drop test, the amount of frequency variation was measured in the case where a hard wooden board free falls from a height of 100 cm while varying the rotation angle in plane in a range of 0 degrees to 90 degrees. The free falls were performed three times for each sample. FIG. 10 indicates the result including maximum, minimum, and average of the amount of frequency variation of the tested six samples. As shown in FIG. 10, the amount of frequency variation has the maximum value at a rotation angle in plane Ψ of 45 degrees.

Techniques relate to crystal units include Japanese Unexamined Patent Application Publication No. 2004-096568 “IT-cut crystal unit”, (NIHON DEMPA KOGYO CO., LTD., hereinafter referred to as Patent Literature 1) and Japanese Unexamined Patent Application Publication No. 2008-099230 “SC-cut crystal unit and high-stability crystal oscillator”, (Epson Toyocom Corporation, hereinafter referred to as Patent Literature 2).

Patent Literature 1 discloses a configuration of an IT-cut crystal unit held at at least one pair of edge portions that face one another. The edge portions are portions where a displacement of a plate surface of a crystal element is small. The edge portions are located at rotation angles of 18 degrees±18 degrees and 198 degrees±18 degrees from Z axis and at rotation angles of 108 degrees±18 degrees and 288 degrees±18 degrees from Z axis. Patent Literature 2 discloses a configuration of an SC-cut crystal unit held at two points. These two points are located on a line at one rotation angle of 80 degrees to 90 degrees, 165 degrees to 180 degrees, 140 degrees to 150 degrees, or 0 degrees to 5 degrees from ZZ′ axis. ZZ′ axis is obtained by rotating counter clockwise from respective Z axis and X axis.

However, a problem arises in that the conventional IT-cut crystal unit has the large frequency shift after the power turns on, thus causing varied aging characteristics. The conventional IT-cut crystal unit has a problem in that a displaced rotation of the crystal element causes varied environmental resistance characteristics.

A need thus exists for a crystal unit which is not susceptible to the drawback mentioned above.

### SUMMARY

In order to solve the above-identified problem, this disclosure provides a crystal unit with an IT-cut round crystal element. The crystal element is supported at two points on an outer periphery portion of the crystal element. A rotation angle in plane between a straight line connecting the two points and Z″ axis of a double-rotation is within a specific range. The specific range includes an angle where an amount of frequency variation is zero.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a schematic explanatory view illustrating a configuration of a crystal unit according to a first embodiment of this disclosure;

FIG. 2 is an explanatory view illustrating a rotation angle in plane Ψ in an IT-cut crystal unit;

FIG. 3 is a graph illustrating a relationship between a rotation angle in plane Ψ and a frequency aging of a crystal element in the IT-cut crystal unit;

FIG. 4 is a schematic explanatory view illustrating supporting positions for a crystal element of a first crystal unit;

FIG. 5 is a schematic explanatory view illustrating a shape of a crystal element in a second crystal unit;

FIG. 6A is a front explanatory view illustrating a configuration of the second crystal unit;

FIG. 6B is a side explanatory view illustrating the configuration of the second crystal unit;

FIG. 6C is a partial enlarged explanatory view illustrating a tip section of a supporter in the second crystal unit;

FIG. 7A is a front explanatory view illustrating a configuration of a modification of the second crystal unit;

FIG. 7B is a side explanatory view illustrating the configuration of the modification of the second crystal unit;

FIG. 7C is a partial enlarged explanatory view illustrating a tip section of a supporter in the modification of the second crystal unit;

FIG. 8 is a graph illustrating an exemplary aging characteristic of a conventional IT-cut crystal unit;

FIG. 9 is a graph illustrating a result of a heat cycle test of the conventional IT-cut crystal unit; and

FIG. 10 is a graph illustrating a result of a drop test of the conventional IT-cut crystal unit.

### DETAILED DESCRIPTION

### Outline of Embodiment

A description will be given of an embodiment of the disclosure by referring to the drawings. A crystal unit according to the embodiment of the disclosure employs an IT-cut round crystal element. The crystal element has a configuration supported at two points on an outer periphery portion. A straight line connecting these two points has a rotation angle in plane Ψ of −12 degrees to +4 degrees or +60 degrees to +80 degrees from Z″ axis of a double-rotation. This ensures a reduced frequency shift after the power turns on, thus improving aging characteristics.

The crystal unit according to the embodiment of the disclosure includes a crystal element with two edge portions supported by a supporter and an L-shaped cutout below the two edge portions in the above-described crystal unit. Further, the supporter has a shape with a slit engaging the L-shaped cutout of the crystal element so as to hold the crystal element such that an angle of the crystal element is not displaced. This ensures satisfactory aging characteristics.

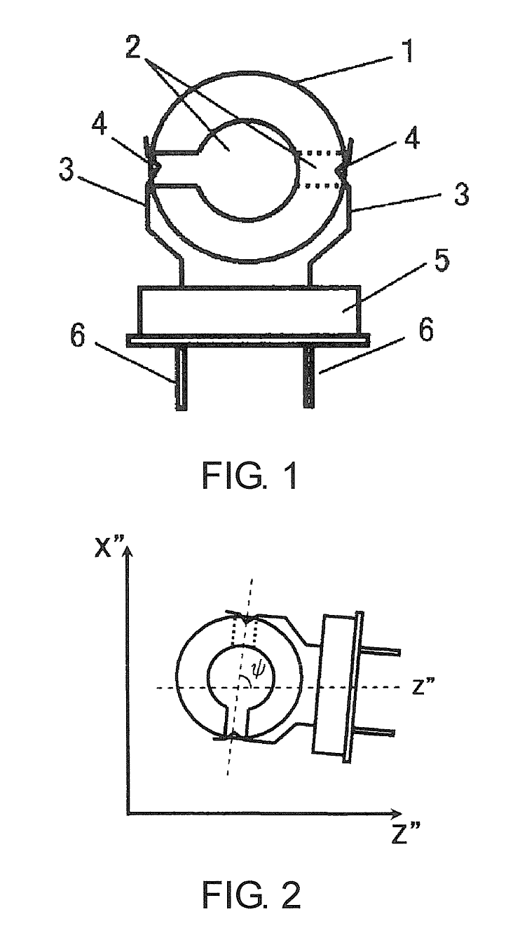

### Configuration of a Crystal Unit According to a First Embodiment (See FIG. 1)

FIG. 1 is a schematic explanatory view illustrating a configuration of a crystal unit according to a first embodiment of this disclosure. As shown in FIG. 1, the crystal unit according to the first embodiment (first crystal unit) includes a crystal element 1, electrodes 2, supporters 3, a conductive adhesive 4, a metal base 5, and a conductive terminal 6.

The crystal element 1 is an IT-cut round crystal blank of a double-rotation cut. The crystal element 1 is supported on the metal base 5 by the two supporters 3 at the two points on the outer periphery portion close to both ends of a diameter. The electrodes 2 are disposed on the front surface and the back surface of the crystal element 1. The electrodes 2 include an excitation electrode disposed at the center portion of the crystal element 1 and an extraction electrode extracted outside from the excitation electrodes. The extraction electrodes, on the front surface and the back surface of the crystal element 1, are extracted to positions (which are positions approximately symmetrical with respect to the center), which face one another.

The supporter 3 supports the crystal element 1 on the metal base 5 and electrically connects to the electrode 2. The supporter 3 bends in “<” shape inward close to the edge portion so as to support the edge portions, which are both ends of the diameter where the extraction electrodes are formed on the crystal element 1. The supporter 3 includes a slit that sandwiches (houses) the edge portions at the bending portion.

The conductive adhesive 4 secures the crystal element 1 to the supporter 3 and electrically connects the electrode 2 and the supporter 3. The conductive terminal 6 is vertically disposed on the principal surface of the metal base 5, electrically connects to the supporter 3, and also conductively connects to outside at the back surface side of the metal base 5.

### Rotation Angle in Plane (See FIG. 2)

FIG. 2 is an explanatory view illustrating a rotation angle in plane Ψ in an IT-cut crystal unit. As shown in FIG. 2, in X″-Z″ plane of the crystallographic axis, an angle Ψ between Z″ axis and the diameter that connects the two points where the supporters 3 support the crystal element 1 centered at Y axis is referred to as rotation angle in plane. Then, the first crystal unit features that the supporter 3 holds the crystal element 1 such that the crystal element 1 has the rotation angle in plane ‘F that is a specific angle to have a decreased frequency aging.

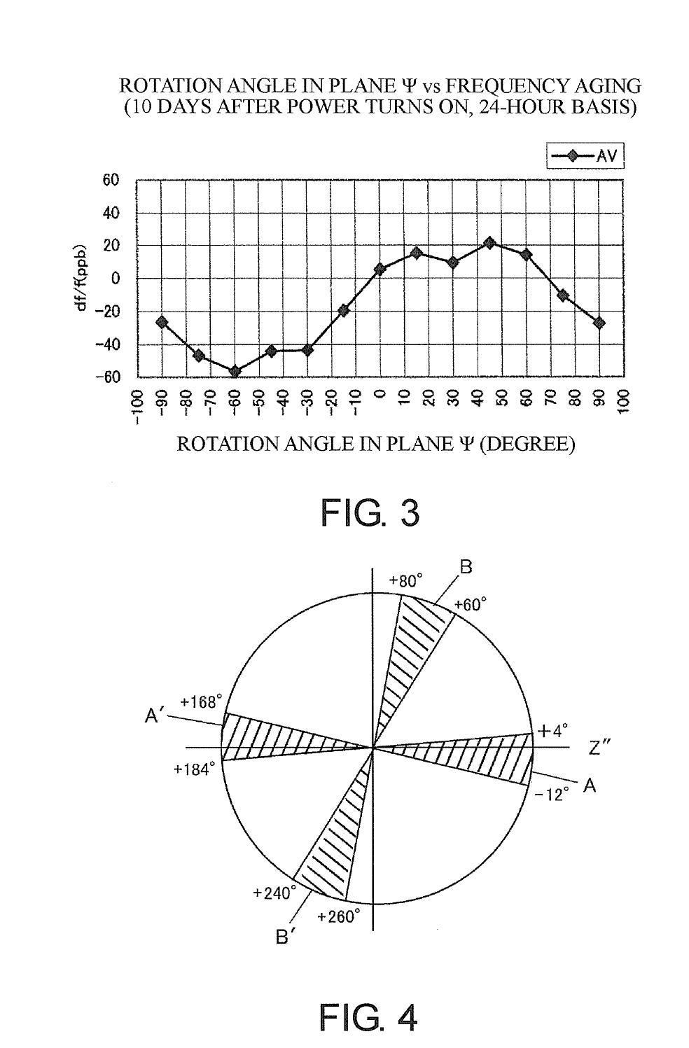

Relation between a Rotation Angle in Plane and a Frequency Aging Variation (See FIG. 3)

Next, a relationship between a rotation angle in plane Ψ of a crystal element in an IT-cut crystal unit and a frequency aging will be described by referring to FIG. 3. FIG. 3 is a graph illustrating a relationship between a rotation angle in plane Ψ and a frequency aging of a crystal element in the IT-cut crystal unit. FIG. 3 illustrates an example of a measurement of a frequency aging 10 days after the power turns on while varying supporting positions of the crystal element 1 within a range of rotation angles in plane Ψ of −90 degrees to +90 degrees.

As shown in FIG. 3, an amount of frequency aging varies depending on a rotation angle in plane Ψ of the crystal element 1, and an amount of frequency variation is nearly zero in some cases. In an example of FIG. 3, an amount of frequency variation is extremely small at rotation angles in plane Ψ of approximately −4 degrees and approximately +70 degrees. The first crystal unit takes advantage of it to reduce the frequency aging as much as possible by supporting the crystal element at a specific rotation angle in plane.

### Supporting Positions of the Crystal Element in the First Crystal Unit (See FIG. 4)

Next, the supporting positions of the crystal element in the first crystal unit will be described by referring to FIG. 4. FIG. 4 is a schematic explanatory view illustrating the supporting positions for the crystal element of the first crystal unit. As shown in FIG. 4, two patterns A and B are assumed for positions of the two points where an IT-cut round crystal element is supported in the first crystal unit.

As shown in FIG. 4, the first crystal unit includes the crystal element held at two kinds of supporting positions, the patterns A and B. In the pattern A, the crystal element is held at a region (A region) at a rotation angle of −12 degrees to +4 degrees (−4 degrees±8 degrees) from Z″ axis and a region (A′ region) in an opposing position at a rotation angle of +168 degrees to +184 degrees (176 degrees±8 degrees) from Z″ axis. In the pattern B, the crystal element is held at a region (B region) at a rotation angle of +60 degrees to +80 degrees (70 degrees±10 degrees) from Z″ axis and a region (B′ region) in an opposing position at a rotation angle of +240 degrees to +260 degrees (+250 degrees±10 degrees) from Z″ axis. That is, the first crystal unit includes extraction electrodes at regions corresponding to these two patterns.

As shown in FIG. 3, these two patterns each include the rotation angle in plane, in which the amount of frequency aging is zero within 10 days after the power turns on, in respective regions. That is, in the first crystal unit, the crystal element is supported on the optimum supporting position at a rotation angle in plane Ψ where the frequency aging is hardly generated. This consequently minimizes the frequency aging of the first crystal unit 10 days after the power turns on and reduces the variation of the aging characteristic, thus ensuring satisfactory vibration characteristics.

A pattern has a region with a narrower angle range than B pattern. This is because A pattern has a larger gradient than B pattern in a graph of FIG. 3 and has a smaller angle margin where an amount of the frequency aging is nearly zero. In the A pattern and B pattern, the angle range may be set to a narrow range of approximately ±5 degrees from the center where the frequency aging is zero so as to further improve the accuracy. In any pattern, the width from the center may be set corresponding to a required specification as necessary.

### Effect of the First Embodiment

With the crystal unit according to the first embodiment of the disclosure, the crystal element 1 is supported at an angle within a range of rotation angles in plane of −12 degrees to +4 degrees or 60 degrees to 80 degrees. The rotation angle in plane is an angle between Z″ axis of the crystallographic axis and the straight line connecting the two points at which the IT-cut round crystal element is supported. These two points are opposed on the outer periphery of the IT-cut round crystal element. This almost eliminates the frequency aging within 10 days after the power turns on and reduces the variation of the aging characteristic, thus giving an effect of improving the frequency stability.

### Another Crystal Unit According to a Second Embodiment

Next, a description will be given of a crystal unit according to the second embodiment of the disclosure. The other crystal unit (second crystal unit) according to the second embodiment of the disclosure includes improved shapes of the crystal element and the supporter in the above-described first crystal unit so as to prevent the crystal element from being displaced from the optimum supporting position (optimum rotation angle in plane) due to rotation of the crystal element. This further improves the frequency stability.

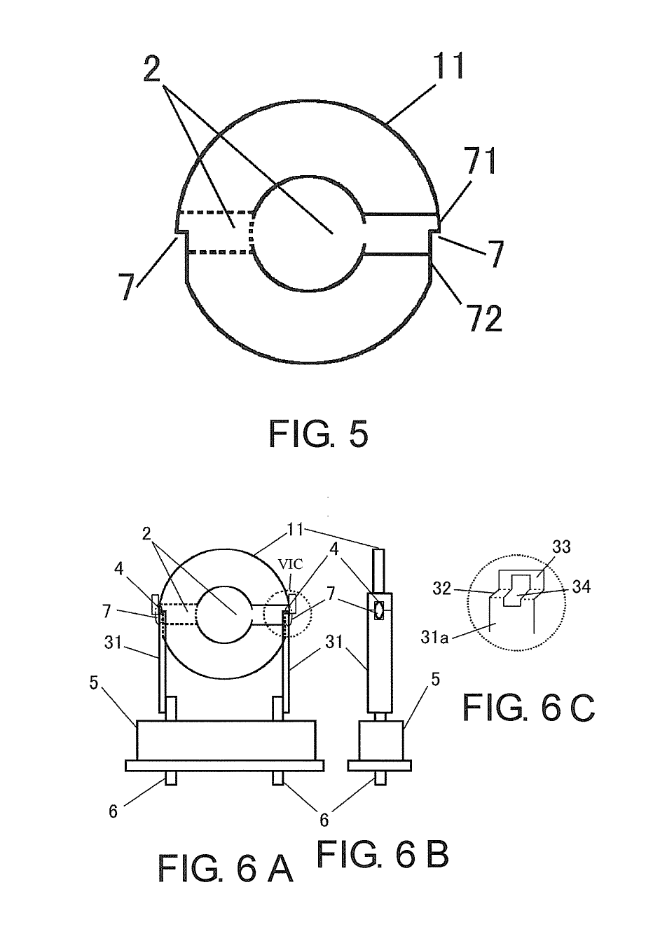

### The Shape of the Crystal Element in the Second Crystal Unit (See FIG. 5)

First, the shape of the crystal element in the second crystal unit will be described by referring to FIG. 5. FIG. 5 is a schematic explanatory view illustrating the shape of the crystal element in the second crystal unit. As shown in FIG. 5, the crystal element 11 of the second crystal unit is an IT-cut round crystal element and includes the electrodes 2 on both surfaces. Both ends of the extraction electrodes are the portions supported by the supporters. Here, the positions of both ends of the extraction electrodes are inside of the region where the angle between Z″ axis and the straight line connecting both ends is the above-described optimum rotation angle in plane Ψ. The frequency aging is hardly generated at the supporting positions.

The second crystal unit has a feature where two supporting portions of the crystal element 11 have L-shaped notched portions 7. The two supporting portions include the extraction electrodes and are supported by the supporters. The notched portions 7 include the two L-shaped sides with a horizontal portion 71 and a vertical portion 72. The horizontal portion 71 heads for the center from the supporting positions of the crystal element 1. The vertical portion 72 is formed vertically downward toward the metal base 5 from the end portion of the horizontal portion 71 closer to the center. The horizontal portions 71 of the two notched portions 7 are formed at the optimum supporting positions (in the region) corresponding to one of the patterns A, B, and C described in the description of the first crystal unit.

### Configuration of the Second Crystal Unit (see FIGS. 6A to 6C)

The configuration of the second crystal unit will be described by referring to FIGS. 6A to 6C. FIG. 6A is a front explanatory view illustrating a configuration of the second crystal unit. FIG. 6B is a side explanatory view illustrating the configuration of the second crystal unit. FIG. 6C is a partial enlarged explanatory view illustrating a tip section of a supporter in the second crystal unit. As shown in FIGS. 6A and 6B, the second crystal unit has the basic configuration similar to the first crystal unit shown in FIG. 1. The second crystal unit includes a crystal element 11, electrodes 2, supporters 31, a conductive adhesive 4, the metal base 5, and the conductive terminals 6. The crystal element 11 is mounted above the metal base 5 by the two supporters 31. The crystal element 11 has the shape with the notched portions 7 as shown in FIG. 5. As described below, the supporter 31 has the shape different from the supporter 3 of the first crystal unit. The other configuration is similar to that of the first crystal unit and will not be further elaborated here.

As shown in FIG. 6C, the supporter 31 of the second crystal unit includes a supporter main body 31a, a first projecting portion 32, and a second projecting portion 33. The supporter main body 31a is vertically mounted on the metal base 5. The first projecting portion 32 projects outside (the opposite side of the center direction of the crystal element 11) from the supporter main body 31a. The second projecting portion 33 further projects from the first projecting portion 32 approximately vertically toward the opposite side of the metal base 5. Further, the slit 34 is formed continuously from the supporter main body 31 a across the first projecting portion 32 and the second projecting portion 33.

In the case where the second crystal unit includes the crystal element 11 mounted on the supporters 31, the horizontal portion 71 of the notched portion 7 in the crystal element 11 engages (catches) the end portion of the slit 34 at the supporter main body 31 a side and is supported by the supporter 31.

Additionally, an upper side of the outer periphery of the crystal element 11 with respect to the notched portion 7 partially fits into the slit 34 at the side of the second projecting portion 33 while this upper side part partially projects outside. The portion where the slit 34 of the supporter 31 and the crystal element 11 contact one another is bonded by the conductive adhesive 4. The two supporters 31 are arranged with an appropriate spacing on the metal base 5 such that the crystal element 11 with the notched portions 7 engages, is housed in, and is mounted on the slit 34, as described above.

Accordingly, with the second crystal unit, the notched portions 7 at two positions formed at the optimum supporting positions in the crystal element 11 engages the end portion of the slit 34 at the supporter main body 31a side. Additionally, the upper outer periphery portion of the notched portion 7 in the crystal element 11 is housed in the slit 34 formed on the second projecting portion 33. This prevents the mounted crystal element 11 from rotating and maintains the crystal element 11 in a supported state at the optimum position (at the optimum rotation angle in plane), thus ensuring a satisfactory aging characteristic.

Additionally, the second crystal unit allows the rotation angle in plane to be kept in the predetermined value. This reduces an individual difference between the crystal units, thus ensuring the reduced variations of resistance properties against heat cycle and impact.

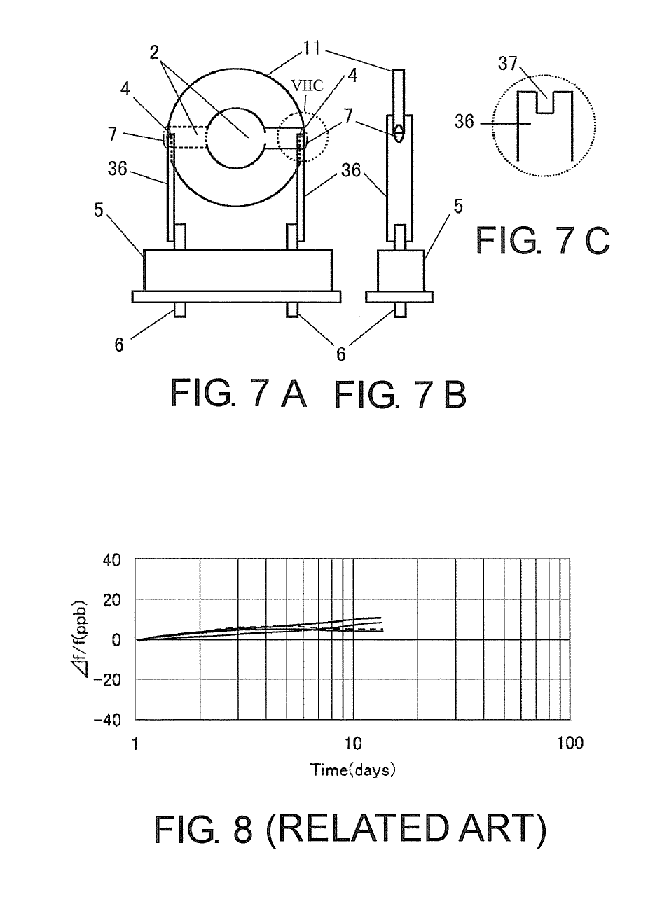

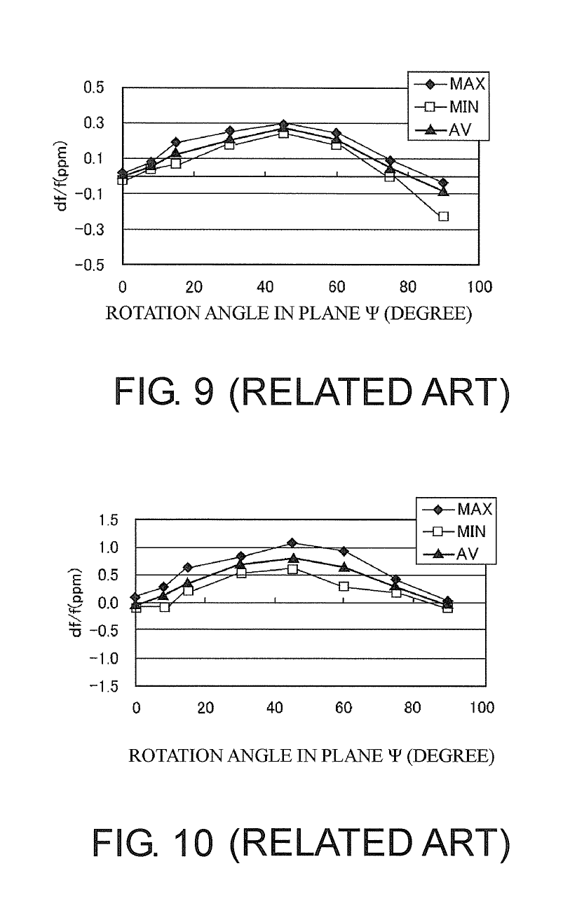

### Modification of the Second Crystal Unit (See FIGS. 7A to 7C)

Next, a modification of the second crystal unit will be described by referring to FIGS. 7A to 7C. FIG. 7A is a front explanatory view illustrating a configuration of a modification of the second crystal unit. FIG. 7B is a side explanatory view illustrating the configuration of the modification of the second crystal unit. FIG. 7C is a partial enlarged explanatory view illustrating a tip section of a supporter in the modification of the second crystal unit. While in the modification of the second crystal unit, the crystal element 11 with the notched portions 7 shown in FIG. 5 is employed similarly to the second crystal unit, the modification includes a supporter with a simpler shape. The modification is otherwise similar to the second crystal unit.

As shown in FIGS. 7A and 7B, in the modification, the two supporters 36 vertically hold the crystal element 11 with the notched portions 7 on the metal base 5. As shown in FIG. 7C, the supporter 36 according to the modification includes a slit 37 at its tip section.

With the modification, when the crystal element 11 is mounted, the horizontal portion 71 of the notched portion 7 engages the slit 37 of the supporter 36 and is supported.

A supporter 36 according to the modification is different from the supporter 31 according to the second crystal unit in that the supporter 36 does not includes the slit to house the upper outer periphery portion of the notched portion 7 in the crystal element 11. Thus, the supporter 36 according to the modification is slightly inferior in stabilization of holding the crystal element 11. However, the supporter 36 according to the modification achieves the effect for preventing the crystal element 11 from rotating to hold the optimum rotation angle in plane, thus ensuring a significantly simplified manufacturing process of the supporter excellent at mass production.

### Effect of the Second Embodiment

The crystal unit according to the second embodiment of the disclosure is a crystal unit with an IT-cut round crystal element 11. The IT-cut round crystal element 11 includes the horizontal portions 71 and the notched portions 7. The horizontal portions 71 are disposed at both ends of the diameter where the rotation angle in plane from Z″ axis is the optimum angle. The notched portion 7 is L-shaped where the lower side of the horizontal portion 71 is vertically cut out. The horizontal portion 71 of the notched portion 7 engages the slit disposed in the supporter 31 (or the supporter 36) so as to prevent the crystal element 11 from rotating to maintain the crystal element 11 held in the optimum rotation angle in plane. This achieves the effect for ensuring the preferred aging characteristics and the reduced variations of environmental resistance properties against heat cycle and impact.

With the second crystal unit according to the second embodiment of the disclosure, the supporter 31 includes the tip section that is folded in two places to include the first projecting portion 32 and the second projecting portion 33. The supporter 31 includes the slit 34 that is continuously formed from the supporter main body 31 a across the first projecting portion 32 and the second projecting portion 33. When the crystal element 11 with the notched portion 7 is mounted, the horizontal portion 71 of the notched portion 7 engages the end portion of the slit 34 at the supporter main body 31 a side, and the upper outer periphery portion of the notched portion 7 is housed in the slit 34 at the second projecting portion 33 side. This allows the supporters 31 to further stably hold the crystal element 11, thus giving an effect of ensuring the reduced variation as a further satisfactory characteristic.

The disclosure is suitable for an IT-cut crystal unit that improves the aging characteristics and reduces the variation in environmental resistance characteristics.

In the crystal unit according to the disclosure, the specific range may be one of a range where the rotation angle in plane from Z″ axis is in a range of −12 degrees to +4 degrees and a range where the rotation angle in plane from Z″ axis is in a range of +60 degrees to +80 degrees.

The crystal unit according to the disclosure may be configured as follows. The crystal element includes a notched portion at positions of the supported two points. The crystal unit further includes a supporter that supports the crystal element. The supporter includes a slit engaging the notched portion. The notched portion includes a horizontal portion and a vertical portion. The horizontal portion is formed from the supported point toward the center of the crystal element. The vertical portion is formed vertically downward from the end portion of the horizontal portion close to the center. The horizontal portion of the notched portion engages the slit of the supporter to support the crystal element.

The crystal unit according to the disclosure may be configured as follows. The supporter includes: a first projecting portion, a second projecting portion, and a slit. The first projecting portion projects toward an opposite direction of a direction to the center of the crystal element from a main body of the supporter (i.e, a support main body). The second projecting portion further projects upward from the first projecting portion. The slit is continuously formed from the main body of the supporter across the first projecting portion and the second projecting portion. The horizontal portion of the notched portion of the crystal element engages the end portion of the slit foamed on the main body of the supporter, and the upper side of the outer periphery portion with respect to the notched portion of the crystal element is housed in the slit formed on the second projecting portion to support the crystal element.

According to the disclosure, the crystal unit includes an IT-cut round crystal element supported at two points on an outer periphery portion of the IT-cut round crystal element. A rotation angle in plane between a straight line connecting the two points and Z″ axis of a double-rotation is within a specific range. The specific range includes an angle where an amount of frequency variation is zero. This consequently gives an effect that extremely minimizes an amount of frequency aging to suppress the frequency shift after the power turns on, and to improve the aging characteristic.

According to the disclosure, the crystal element includes a notched portion at positions of the supported two points. The crystal unit further includes a supporter that supports the crystal element. The supporter includes a slit engaging the notched portion. The notched portion includes a horizontal portion and a vertical portion. The horizontal portion is formed from the supported point toward the center of the crystal element. The vertical portion is formed vertically downward from the end portion of the horizontal portion close to the center. The horizontal portion of the notched portion engages the slit of the supporter to support the crystal element. This prevents the crystal element from rotating and being displaced from the optimum rotation angle in plane and maintains the crystal element supported at the optimum position, thus giving effects of ensuring the satisfactory aging characteristics and the reduced variation in environmental resistance characteristics.

According to the disclosure, the supporter includes a first projecting portion, a second projecting portion, and a slit. The first projecting portion projects toward an opposite direction of a direction to the center of the crystal element from a main body of the supporter. The second projecting portion further projects upward from the first projecting portion. The slit is continuously formed from the main body of the supporter across the first projecting portion and the second projecting portion. The horizontal portion of the notched portion of the crystal element engages the end portion of the slit formed on the main body of the supporter, and the upper side of the outer periphery portion with respect to the notched portion of the crystal element is housed in the slit formed on the second projecting portion to support the crystal element. This allows the crystal element to be secured to the supporter at the two points of the horizontal portion of the notched portion of the crystal element and the upper outer periphery portion of the notched portion so as to firmly hold the crystal element, thus giving effects of ensuring the further stabilized aging characteristics and the reduced variation in environmental resistance characteristics.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A crystal unit, comprising:
an IT-cut round crystal element, supported at two points on an outer periphery portion of the IT-cut round crystal element, wherein
a rotation angle in plane between a straight line connecting the two points and Z″ axis of a double-rotation is within a specific range, the specific range including an angle where an amount of frequency variation is zero.

2. The crystal unit according to claim 1, wherein
the specific range is one of a range where the rotation angle in plane from Z″ axis is in a range of −12 degrees to +4 degrees and a range where the rotation angle in plane from Z″ axis is in a range of +60 degrees to +80 degrees.

3. The crystal unit according to claim 1, wherein
the crystal element includes a notched portion at positions of the supported two points, wherein the crystal unit further comprises:
a supporter that supports the crystal element, the supporter including a slit engaging the notched portion, wherein
the notched portion includes a horizontal portion and a vertical portion, the horizontal portion being formed from the supported point toward the center of the crystal element, and the vertical portion being formed vertically downward from the end portion of the horizontal portion close to the center, and
the horizontal portion of the notched portion engages the slit of the supporter to support the crystal element.

4. The crystal unit according to claim 2, wherein
the crystal element includes a notched portion at positions of the supported two points, wherein the crystal unit further comprises:
a supporter that supports the crystal element, the supporter including a slit engaging the notched portion, wherein
the notched portion includes a horizontal portion and a vertical portion, the horizontal portion being formed from the supported point toward the center of the crystal element, and the vertical portion being formed vertically downward from the end portion of the horizontal portion close to the center, and
the horizontal portion of the notched portion engages the slit of the supporter to support the crystal element.

5. The crystal unit according to claim 3, wherein
the supporter includes: a first projecting portion, a second projecting portion, and a slit,
the first projecting portion projecting toward an opposite direction of a direction to the center of the crystal element from a main body of the supporter,
the second projecting portion further projecting upward from the first projecting portion, and
the slit being continuously formed from the main body of the supporter across the first projecting portion and the second projecting portion, and
the horizontal portion of the notched portion of the crystal element engages the end portion of the slit formed on the main body of the supporter, and the upper side of the outer periphery portion with respect to the notched portion of the crystal element is housed in the slit formed on the second projecting portion to support the crystal element.

6. The crystal unit according to claim 4, wherein
the supporter includes: a first projecting portion, a second projecting portion, and a slit,
the first projecting portion projecting toward an opposite direction of a direction to the center of the crystal element from a main body of the supporter,
the second projecting portion further projecting upward from the first projecting portion, and
the slit being continuously formed from the main body of the supporter across the first projecting portion and the second projecting portion, and
the horizontal portion of the notched portion of the crystal element engages the end portion of the slit formed on the main body of the supporter, and the upper side of the outer periphery portion with respect to the notched portion of the crystal element is housed in the slit formed on the second projecting portion to support the crystal element.
